(19) United States
(12) Patent Application Publication
(10) Pub. No.: US 2009/0139569 A1
(43) Pub. Date: Jun. 4, 2009

(54) Method of manufacturing photoelectric conversion device, and photoelectric conversion device

(75) Inventors: Masahiro Tsuchiya, Tokyo (JP); Tokuhiko Handa, Tokyo (JP); Atsushi Monden, Tokyo (JP); Masahiro Shinkai, Tokyo (JP)

Correspondence Address: OLIFF & BERRIDGE, PLC, P.O. BOX 320850, ALEXANDRIA, VA, 22320-4850, US

(73) Assignee: TDK CORPORATION, Tokyo (JP)

(21) Appl. No.: 12/292,830

(22) Filed: Nov. 26, 2008

(30) Foreign Application Priority Data
Nov. 29, 2007 (JP) 2007-308637
Oct. 21, 2008 (JP) 2008-271093

(51) Int. Cl. H01L 31/00; B05D 5/06

(52) U.S. Cl. 136/256; 427/74

(57) ABSTRACT

Provided is a method of manufacturing a photoelectric conversion device capable of maintaining a durability and improving initial characteristics. A dye-sensitized photoelectric conversion device including a working electrode and a facing electrode, and an electrolyte inclusion is manufactured. First, a facing electrode in which a dye is carried by a metal oxide semiconductor layer having a porous structure, and a facing electrode are manufactured. Next, the working electrode and the facing electrode are stuck together so as to have a predetermined space in between. A low-viscosity liquid is injected between the working electrode and the facing electrode and impregnated into the porous structure. Then, the high-viscosity material is injected and the electrolyte is adjusted so as to form the electrolyte inclusion. Even if the viscosity of the electrolyte is high, an electrolytic salt is quickly dispersed into the porous structure.

### CROSS REFERENCES TO RELATED APPLICATIONS

The present invention contains subject matter related to Japanese Patent Applications JP2007-308637 filed on Nov. 29, 2007 and JP2008-271093 filed on Oct. 21, 2008 in the Japanese Patent Office, the entire contents of which being incorporated herein by reference.

### BACKGROUND OF THE INVENTION

1. Field of the Invention

The present invention relates to a method of manufacturing a photoelectric conversion device by using a dye, and a photoelectric conversion device manufactured by such a method.

2. Description of the Related Art

A dye-sensitized photoelectric conversion device using a dye as a photosensitizer has been known as a photoelectric conversion device such as a solar cell and the like, which converts light energy such as sunlight into electrical energy. This dye-sensitized photoelectric conversion device is theoretically expected to have high efficiency, and it is thought that the dye-sensitized photoelectric conversion device is advantageous in terms of cost in comparison with a widely-distributed photoelectric conversion device using silicon semiconductor. Thus, the dye-sensitized photoelectric conversion device has attracted attention as a photoelectric conversion device of the next generation, and the development has been in progress for practical use.

The dye-sensitized photoelectric conversion device utilizes a characteristic that the dye absorbs light and emits electrons, thereby performs electric generation. The dye-sensitized photoelectric conversion device characteristically has an electrochemical cell structure via an electrolytic solution. Specifically, the dye-sensitized photoelectric conversion device has such a configuration that an oxide semiconductor such as titanium oxide is used and burned so as to form a porous layer, and an electrode which absorbs the dye and the electrode as a counter electrode are stuck together with an electrolytic solution in between. As a method of manufacturing the cell structure, there is known a method where pores for injecting the electrolytic solution are opened on one of the electrodes, and both of the electrodes face each other so as to have a predetermined space in between. Then, the electrolytic solution is injected from the pores for injecting the electrolytic solution (for example, refer to Japanese Unexamined Patent Publication No. 2007-123088).

As the electrolytic solution, a redox electrolytic salt dissolving in solvent is generally used. The solvent contains acetonitrile as a principle component, because the high conversion efficiency is achieved. In recent years, in order to improve the characteristics such as the photoelectric conversion efficiency and safety, an ionic liquid, a quaternary ammonium salt, and the like which function as the redox electrolytic salt as well as the solvent are used. Such a technology is disclosed in some patent documents listed as follows.

### Japanese Unexamined Patent Publication No. 2005-085587

### Japanese Unexamined Patent Publication No. 2005-093075

### Japanese Unexamined Patent Publication No. 2005-347176

### Japanese Unexamined Patent Publication No. 2004-134200

### Japanese Unexamined Patent Publication No. 2004-319197

### Japanese Unexamined Patent Publication No. 2007-073346

### Japanese Unexamined Patent Publication No. 2007-095480

### International Publication No. 2005/006482 Pamphlet

### Japanese Unexamined Patent Publication No. 2002-175842

### Japanese Unexamined Patent Publication No. 2005-251736

### Japanese Unexamined Patent Publication No. 2002-075470

### Japanese Unexamined Patent Publication No. 2005-071688

### Japanese Unexamined Patent Publication No. 2007-141473

### Published Japanese Translation of the PCT International Publication No. 2005-530894

### SUMMARY OF THE INVENTION

However, in the case where the electrolytic solution containing a solvent such as acetonitrile with a high volatility as a principle component is used, the electrolytic solution is converted into gas in the cell structure under a high-temperature environment. Accordingly, there are issues that a leakage easily occurs and a sufficient durability is hardly obtained. In the case where the electrolyte containing ionic liquid or the like with a low volatility is used, the viscosity of the electrolyte becomes high. Accordingly, there are issues that it takes time until the electrolyte infiltrates into the porous layer of the electrode, and sufficient initial characteristics are hardly obtained.

In view of the foregoing, it is desirable to provide a method of manufacturing a photoelectric conversion device capable of improving initial characteristics while maintaining a durability, and a photoelectric conversion device manufactured by such a manufacturing method.

Other and further objects, features and advantages of the invention will appear more fully from the following description.

According to an embodiment of the present invention, there is provided a method of manufacturing a photoelectric conversion device including forming an electrolyte inclusion between a working electrode and a facing electrode. The working electrode has a porous structure which carries a dye and the facing electrode faces the working electrode on the porous structure side. Forming the electrolyte inclusion includes impregnating the porous structure with a low viscosity liquid, and then filling, between the working electrode and the facing electrode, a high-viscosity material having a viscosity higher than that of the low-viscosity liquid. Here, the expression “material having a high viscosity” means a liquid material having a viscosity higher than the low-viscosity liquid. The high-viscosity material may be a liquid, a liquid in slurry state or sol state, or a semi-solid in gel state or paste state.

According to an embodiment of the present invention, in the method of manufacturing the photoelectric conversion device, the step of forming the electrolyte inclusion includes impregnating the low-viscosity liquid into the porous structure, and then filling, between the working electrode and the facing electrode, the high-viscosity material having a viscosity higher than the low-viscosity liquid. Thereby, the low-viscosity liquid functions so as to improve a wettability of the porous structure, and at least a part of compositions in the high-viscosity material easily infiltrates into the porous structure. Several methods are available for impregnating the electrolytes in the step of forming the electrolyte inclusion. For example, the high-viscosity material may contain the electrolytic salt. In this case, the electrolytic salt is quickly diffused in the porous structure. Alternatively, the low-viscosity liquid may contain the electrolytic salt. In this case, the electrolytic salt in the porous structure is diffused in the high-viscosity material. Obviously, both of the high-viscosity material and the low-viscosity liquid may contain the electrolytic salt. Moreover, the step of impregnating the electrolytic salt between the working electrode and the facing electrode may be included, separately from the step of impregnating the low-viscosity liquid and the step of filling the high-viscosity material. In this case, the electrolyte is also quickly diffused in the porous structure. Thereby, in any of these cases, in the formed electrolyte inclusion at least at an initial stage, the electrolyte having a low viscosity is distributed so as to be enclosed in the porous structure. Thus, the electron quickly travels between the working electrode and the electrolyte inclusion in the photoelectric conversion device at the initial stage. Moreover, a large part of the electrolyte inclusion is composed of electrolytes having a high viscosity. Therefore, the leakage of the electrolyte is suppressed even under the high-temperature environment. Here, the term “electrolyte” indicates an electrolytic salt itself or a material containing an electrolytic salt. For example, the electrolyte includes an ionic liquid as a liquid electrolytic salt, an electrolytic solution in which an electrolytic salt is dissolved in a solvent, and a material containing an electrolytic salt and an electrolytic solution as well as a support material such as a particle and a high polymer compound.

According to an embodiment of the present invention, in the method of manufacturing the photoelectric conversion device, the low-viscosity liquid is preferably a liquid having a viscosity of 0.3 mPa-s or more. The high-viscosity material is preferably a material having a viscosity of 1.9 mPa-s or more. Moreover, as described above, at least one of the low-viscosity liquid and the high-viscosity material preferably contains an electrolytic salt. Thereby, the electron quickly travels between the working electrode and the electrolyte inclusion in the photoelectric conversion device at the initial stage. The leakage of the electrolytes is suppressed even under the high-temperature environment.

According to an embodiment of the present invention, in the method of manufacturing the photoelectric conversion device, the high-viscosity material may contain at least one of a metal oxide particle and a carbon particle. The metal oxide particle may include at least one of a zinc oxide particle and titanium oxide particle, and the carbon particle may include at least one of carbon black and carbon nanotube. Thereby, the electrolyte as a whole is formed so as to have the electrolyte having a higher viscosity so that the leakage of the electrolytes is suppressed even under the high-temperature environment.

According to an embodiment of the present invention, there is provided a photoelectric conversion device including a working electrode having a porous structure which carries a dye, a facing electrode facing the working electrode on the porous structure side, and an electrolyte inclusion provided between the working electrode and the facing electrode, and containing a first electrolyte and a second electrolyte. The first electrolyte has a viscosity lower than that of the second electrolyte, and a concentration ratio of the first electrolyte to the second electrolyte is higher in a region of the porous structure of the working electrode as compared with in a rest region.

According to an embodiment of the present invention, in the photoelectric conversion device, when the dye carried by the porous structure of the working electrode 10 is subjected to light, the dye is erected by absorbing the light and injects the electron into the porous structure. Thus, the electron travels to the facing electrode. On the other hand, in the electrolyte inclusion, a redox reaction is repeated in accordance with the travel of the electron between the working electrode and the facing electrode. Thus, the electron continuously travels between the working electrode, the facing electrode, and the electrolyte inclusion so that the photoelectric conversion is constantly performed. In the case where the photoelectric conversion device is manufactured by the manufacturing method described above, at least at the initial stage, the electrolyte inclusion has a configuration as described in the following. The electrolyte inclusion contains the first electrolyte and the second electrolyte having a viscosity higher than that of the first electrolyte, and the concentration ratio of the first electrolyte to the second electrolyte is higher in a region of the porous structure of the working electrode as compared with a rest region. Thus, the electron quickly travels between the working electrode and the electrolyte inclusion in the initial state of the photoelectric conversion device so that superior initial characteristics are obtained. Moreover, a large part between the working electrode and the facing electrode contains the electrolyte having a high viscosity so that the leakage of the electrolyte is suppressed even under the high-temperature environment.

According to an embodiment of the present invention, in the photoelectric conversion device, the viscosity of the second electrolyte is preferably 1.9 mPa-s or more. Thereby, the electrolyte hardly leaks even under the high-temperature environment.

According to an embodiment of the present invention, in the method of manufacturing the photoelectric conversion device, the low-viscosity liquid is impregnated into the porous structure, and then there is a step of filling, between the working electrode and the facing electrode, the high-viscosity material having a viscosity higher than the low-viscosity liquid. Thereby, the leakage of the electrolyte is suppressed and the durability is maintained. The electron quickly travels between the electrolyte inclusion and the working electrode in the initial state so that the initial characteristics are improved. When the liquid having a viscosity of 0.3 mPa-s or more is used as the low-viscosity liquid, or the material having a viscosity of 1.9 mPa-s or more is used as the high-viscosity liquid, the initial characteristics are improved and the high durability is achieved. When at least one of the low-viscosity liquid and the high-viscosity liquid contains the electrolytic salt, the manufacturing process may be simplified. Especially, when both of the low-viscosity liquid and the high-viscosity material contain the electrolytic salt, the initial characteristics are further improved.

According to an embodiment of the present invention, the photoelectric conversion device includes an electrolyte inclusion containing a first electrolyte and a second electrolyte. The first electrolyte has a viscosity lower than that of the second electrolyte, and a concentration ratio of the first electrolyte to the second electrolyte is higher in the porous structure of the working electrode in comparison with a region except in the porous structure. Thus, the durability is maintained and the initial characteristics are improved. When the second electrolyte has a viscosity of 1.9 mPa-s or more, the initial characteristics are improved and the high durability is achieved.

Other and further objects, features and advantages of the invention will appear more fully from the following description.

### BRIEF DESCRIPTION OF THE DRAWINGS

FIG. 1 is a cross-sectional view illustrating the configuration of a photoelectric conversion device according to an embodiment of the present invention.

FIG. 2 is an enlarged cross-sectional view selectively illustrating a main part of the photoelectric conversion device shown in FIG. 1.

### DETAILED DESCRIPTION OF THE PREFERRED EMBODIMENTS

Preferred embodiments (hereinafter, simply referred to as embodiments) of the present invention will be described in detail with reference to the accompanying drawings.

### First Embodiment

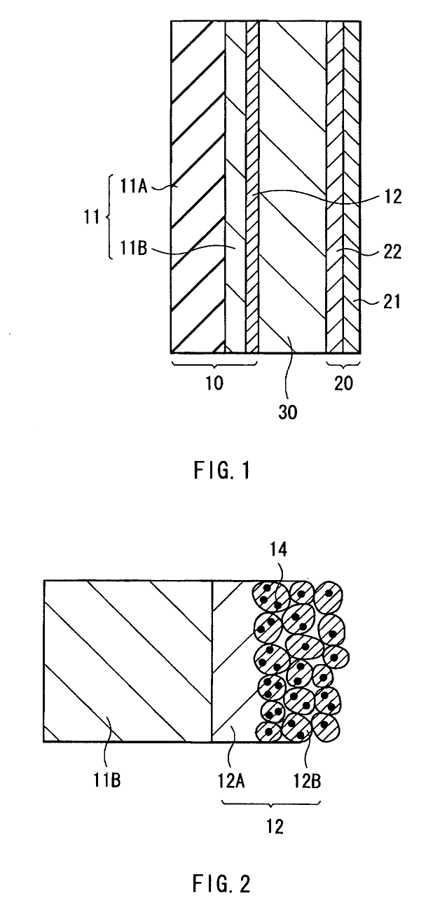

FIG. 1 schematically illustrates the cross-sectional configuration of a photoelectric conversion device according to a first embodiment of the present invention, FIG. 2 selectively illustrates a main part of the photoelectric conversion device in enlarged scale shown in FIG. 1. The photoelectric conversion device shown in FIGS. 1 and 2 corresponds to a main part of a so-called dye-sensitized solar cell. The photoelectric conversion device includes a working electrode 10 and a facing electrode 20 facing each other with an electrolyte inclusion 30 in between. At least one of the working electrode 10 and the facing electrode 20 is an electrode having light transmissivity.

The working electrode 10 has, for example, a configuration where a metal oxide semiconductor layer 12 is provided on a conductive substrate 11, and a dye 14 is carried by the metal oxide semiconductor layer 12 acting as a carrier. The working electrode 10 functions as a negative electrode to an external circuit. The conductive substrate 11 is, for example, provided with a conductive layer 11B on a surface of an insulating substrate 11A.

Materials for the substrate 11A include, for example, insulating materials such as glass, plastic, and a transparent polymer film. As the transparent polymer film, for example, there are tetraacetyl cellulose (TAC), polyethylene terephthalate (PET), polyethylene naphthalate (PEN), syndiotactic polystyrene (SPS), polyphenylene sulfide (PPS), polycarbonate (PC), polyarylate (PAR), polysulfone (PSF), polyestersulfone (PES), polyetherimide (PEI), cyclinc polyolefin, and phenoxy bromide.

As the conductive layer 11B, for example, there are a conductive metal oxide thin film such as indium oxide, tin oxide, indium-tin composite oxide (ITO) and fluorine-doped tin oxide (FTO: F—SnO₂), a metal thin film such as gold (Au), silver (Ag), and platinum (Pt), and materials formed of conductive high polymer.

The conductive substrate 11 may, for example, have the configuration of a single-layered structure by materials having conductive properties. In that case, materials for the conductive substrate 11 include, for example, conductive metal oxide such as indium oxide, tin oxide, indium-tin composite oxide, and fluorine-doped tin oxide, metal such as gold, silver, and platinum, and a conductive high polymer.

The metal oxide semiconductor layer 12 has a porous structure, and is formed with, for example, a dense layer 12A and a porous layer 12B. The dense layer 12A is formed in the interface between the conductive substrate 11 and the metal oxide semiconductor layer 12. The dense layer 12A is preferably dense, and has few air gaps and a film shape. The porous layer 12B is formed on the surface of the metal oxide semiconductor layer 12 in contact with the electrolyte inclusion 30. The porous layer 12B preferably has a lot of air gaps and the configuration with a large surface area. Especially, the porous layer 12B preferably has the configuration with porous particles attached thereon. The metal oxide semiconductor layer 12 may, for example, be formed to have a porous structure of a single-layered structure.

The metal oxide semiconductor layer 12 is composed of at least one or more materials of metal oxide semiconductor. Materials for the metal oxide semiconductor include, for example, titanium oxide, zinc oxide, tin oxide, niobium oxide, indium oxide, zirconium oxide, tantalum oxide, vanadium oxide, yttrium oxide, aluminum oxide, and magnesium oxide. Materials for the metal oxide semiconductor may include composite materials (mixture, mixed crystal, solid solution, and the like) of one or more materials. Among them, at least one of titanium oxide and zinc oxide is preferably included.

The dye 14 carried by the metal oxide semiconductor layer 12 is excited by absorbing light, and includes one or more dyes capable of injecting into the metal oxide semiconductor layer 12. The dye preferably includes, for example, an electron-withdrawing substituent which may be chemically combined with the metal oxide semiconductor layer 12. As the dye, for example, there is an organic dye such as cyanine type dye, merocyanine disazo type dye, trisazo type dye, anthraquinone type dye, polycyclic quinone type dye, indigo type dye, diphenylmethane type dye, trimethylmethane type dye, quinoline type dye, benzophenone type dye, naphthoquinone type dye, perylene type dye, fluorenone type dye, squarylium type dye, azulenium type dye, perinone type dye, quinacridone type dye, metal-free phthalocyanine type dye, and metal-free porphyrin type dye. Specifically, there is D102 dye (manufactured by Mitsubishi Paper Mills Ltd.) expressed by equation 1. In addition to this, there are, for example, eosin Y, dibromofluorescein, fluorescein, rhodamine B, pyrogallol, dichlorofluorescein, erythrosine B (erythrosine is a registered trademark), fluorescin, and mercurochrome.

### Equation 1

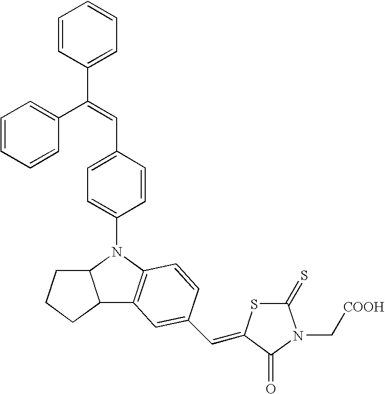

As the dye, for example, there is also an organic metal complex compound, which is exemplified by an organic metal complex compound having both of ionic coordinate bond and nonionic coordinate bond, the ionic coordinate bond formed by nitrogen anion and metallic cation in aromatic heterocycle and the nonionic coordinate bond formed between nitrogen atom or chalcogen atom, and metallic cation, and an organic metal complex compound having both of ionic coordinate bond and nonionic coordinate bond, the ionic coordinate bond formed by oxygen anion or sulfur anion, and metallic cation, and the nonionic coordinate bond formed between nitrogen atom or chalcogen atom, and metallic cation. Specifically, for example, there are metallic phthalocyanine type dye such as copper phthalocyanine and titanyl phthalocyanine, metallic naphthalocyanine type dye, metallic porphyrin type dye, and a ruthenium complex such as a bipyridyl ruthenium complex, a terpyridyl ruthenium complex, a phenanthroline ruthenium complex, a bicinchonic acid ruthenium complex, an azo ruthenium complex, and a quinolinol ruthenium complex.

The facing electrode 20 is, for example, provided with a conductive layer 22 on a conductive substrate 21. The facing electrode 20 functions as a positive electrode to an external circuit. Materials for the conductive substrate 21 include, for example, materials similar to those for the conductive substrate 11 of the working electrode 10. Conductive materials used for the conductive layer 22 include, for example, metal such as platinum, gold, silver, copper (Cu), rhodium (Rh), ruthenium (Ru), aluminum (Al), magnesium (Mg), and indium (In), carbon (C), and a conductive high polymer. These conductive materials may be singly used, or plurally used by mixing them. Also, bond materials such as acrylic resin, polyester resin, phenol resin, epoxy resin, cellulose, melamine resin, fluoroelastomer, and polyimide resin may be optionally used. The facing electrode 20 may, for example, have a single-layered structure of the conductive layer 22.

The electrolyte inclusion 30 contains at least two or more electrolytes. Here, the electrolyte corresponds to a liquid or a material in the liquid state containing an electrolytic salt (electrolytic solution), which is exemplified by an ionic liquid itself as a liquid electrolytic salt, and an electrolytic solution containing a solvent and an electrolytic salt dissolved in the solvent. These electrolytes contain a first electrolyte and a second electrolyte having a viscosity higher than that of the first electrolyte. The concentration ratio of the first electrolyte to the second electrolyte is higher in the porous structure of the metal oxide semiconductor layer 12 in comparison with the region except in the porous structure. That is, the electrolyte present in the porous structure of the metal oxide semiconductor layer 12 has a composition different from that of the region except in the porous structure, for example, that of the electrolyte present on the facing electrode 20 side. Specifically, for example, the first electrolyte has a viscosity lower than that of the second electrolyte. Thus, the viscosity of the electrolyte present in the porous structure of the metal oxide semiconductor layer 12 is lower than that of the electrolyte present in any of the regions except in the porous structure. The viscosity of the second electrolyte is preferably 1.9 mPa-s or more, because the durability is improved.

As the measuring method for investigating that the electrolyte present in the porous structure of the metal oxide semiconductor layer 12 has a composition different from that of the electrolyte present in the region except in the porous structure, there are gas chromatography method (GC), and gas chromatograph mass spectrometer (CC-MS). For the measurement, for example, the electrolyte present in the porous structure and the electrolyte present in the region except in the porous structure are collected. For collecting the electrolyte present in the porous structure, for example, the porous structure is shaved off from the working electrode 10, and the electrolyte is eluted into an organic solvent from a piece shaved off. Then, the respective electrolytes are subjected to GC analysis or GC-MS analysis so that it becomes possible to confirm that the compositions of the electrolytes are different from each other.

These electrolytes contain an electrolytic salt as described above, and optionally contain a solvent such as an organic solvent. As the electrolytic salt, there is a redox electrolytic salt, which is exemplified by I-/I₃-type, Br-/Br₃-type, quinone/hydroquinone type, and the like. As such redox electrolytic salts, for example, a combination between simple halogen and one or more selected from a group consisting of cesium halide, quanternary alkylammonium halide type, imidazolium halide type, thiazolium halide type, oxazolium halide type, quinolinium halide type, and pyridinium halide type may be used. Specifically, cesium iodide, quanternary alkylammonium iodide type such as tetraethylammonium iodide, tetrapropylammonium iodide, tetrabutylammonium iodide, tetrapentylammonium iodide, tetrahexylammonium iodide, tetraheptylammonium iodide and trimethylphenylammonium iodide, imidazolium iodide type such as 3-methylimidazolium iodide and 1-propyl-2,3-dimethylimidazolium iodide, thiazolium iodide type such as 3-ethyl-2-methyl-2-thiazolium iodide, 3-ethyl-5-(2-hydroxyethyl)-4-methylthiazolium iodide and 3-ethyl-2-methylbenzothiazolium iodide, oxazolium iodide type such as 3-ethyl-2-methylbenzoxazolium iodide, quinolinium iodide type such as 1-ethyl-2-methylquinolinium iodide, a combination of iodide and one or more selected from pyridinium iodide type, and a combination of bromine and quarternized alkylammonium bromide may be used.

The redox electrolytic salt preferably contains the ionic liquid as a room-temperature molten salt, because the high durability is achieved. Here, the ionic liquid is usable for battery cells, solar battery cells, and the like. Examples of the ionic liquid are disclosed in “Inorg. Chem” 1996, 35, p. 1168 to p. 1178, “Electrochemistry” 2002, 2, p. 130 to p. 136, Published Japanese Translation of the PCT Patent Application No. Hei-9-507334, Japanese Unexamined Patent Publication No. Hei-8-259543, and the like. Among them, as the ionic liquid, a salt having a melting point lower than a room-temperature (25° C.) is preferable. Alternatively, even in the case where a salt has a melting point higher than the room-temperature, the salt liquefiable by dissolving other molten salt or an additive other than the molten salt is preferable. Specifically, examples of the ionic liquid include an anion and a cation described below.

As the cation in the ionic liquid, for example, there are ammonium, imidazolium, oxazolium, thiazolium, oxadiazolium, triazolium, pyrrolidinium, pyridinium, piperidinium, pyrazolium, pyrimidinium, pyrazinium, triazinium, phosphonium, sulfonium, carbazolium, indolium, and derivatives thereof. These may be singly used or plurally used by mixing them. Among them, at least one selected from a group consisting of ammonium, imidazolium, pyridinium, piperidinium, pyrazolium, sulfonium and derivatives thereof is preferable. Especially, 1-methyl-3-propylimidazolium is preferable, because the sufficient effects are achieved.

As the anion in the ionic liquid, there are metallic chloride such as AlCl₄— and Al₂Cl₇—, fluorine inclusion such as PF₆—, BF₄—, CF₃ SO₃—, N(CF₃SO₂)₂—, F(HF)ₙ—, and CF₃ COO—, non-fluorine inclusion such as NO₃—, CH₃ COO—, C₆H₁₁ COO—, CH₃ OSO₃—, CH₃ OSO₂—, CH₃ SO₂—, CH₃ SO₂—, (CH₃O)₂PO₂—, and SCN—, and halide such as iodine and bromine. These may be singly used or plurally used by mixing them.

The solvent to be used is electrochemically inactive, and preferably has a high viscosity and a high electrical conductivity. This is because the boiling point becomes high due to the high viscosity so that the leakage of the electrolyte is suppressed even under a high-temperature environment, and the high conversion efficiency is achieved due to the high electrical conductivity. As the solvent, for example, there are acetonitrile, dimethyl carbonate, ethyl methyl carbonate, propylene carbonate, ethylene carbonate, γ-butyroalctone, dimethyl sulfoxide, and sulfolane. These may be singly used or plurally used by mixing them. Among them, propylene carbonate and ethylene carbonate are preferable, because the stable conversion efficiency is achieved together with the high durability.

The photoelectric conversion device may, for example, be manufactured by two manufacturing methods described below.

In a first manufacturing method, for example, the metal oxide semiconductor layer 12 having a porous structure is formed by electrolytic deposition on a face where the conductive layer 11B of the conductive substrate 11 is formed. The dye 14 is carried by the metal oxide semiconductor layer 12 so that the working electrode 10 is manufactured. For example, the electrolytic deposition is performed in the following way. An electrolytic bath containing a zinc salt is set at a predetermined temperature while bubbling is performed by oxygen and air. The conductive substrate 11 is dipped in the electrolytic bath with a predetermined voltage applied between the conductive substrate 11 and a counter electrode. At that time, the counter electrode may be appropriately exercised in the electrolytic bath. The metal oxide semiconductor layer 12 may be formed in the following way. For example, powder of a metal oxide semiconductor may be dispersed in a sol of a metal oxide semiconductor so as to obtain a metal oxide slurry. The metal oxide slurry may be applied to the conductive substrate 11 and dried, and then burned. The conductive substrate 11 on which the metal oxide semiconductor layer 12 is formed is dipped in a dye solution which is an organic solvent with the above-mentioned dye dissolved therein, and the dye 14 is carried.

Next, for example, the conductive layer 22 is formed on one surface of the conductive substrate 21, and thereby the facing electrode 20 is manufactured. The conductive layer 22 is, for example, formed by sputtering conductive materials. At this time, pores (not shown in the figure) are made for injecting electrolytes.

Next, the face of the working electrode 10, which carries the dye 14, and the face of the facing electrode 20, where the conductive layer 22 is formed, are stuck together with a spacer (not shown in the figure) such as sealant in between so as to maintain a predetermined space and to face these faces.

Next, a liquid having a low viscosity is injected between the working electrode 10 and the facing electrode 20 through the pores for injecting the electrolytes so that the low-viscosity liquid is impregnated into the metal oxide semiconductor layer 12. Thus, the low-viscosity liquid improves the wettability of the porous structure of the metal oxide semiconductor layer 12, and at least a part of compositions of the liquid high-viscosity material (liquid having a high viscosity) to be injected later easily infiltrates into the porous structure. Thus, even if the viscosity of the electrolyte is high as a whole, the electrolytic salt is easily diffused in the porous structure so that the initial characteristics are improved. Because the electrolyte has a high viscosity, the durability is maintained. The low-viscosity liquid is arbitrarily selected as long as the liquid has a relatively-low viscosity and a viscosity lower than that of the high-viscosity material which will be injected later, and infiltrates into the porous structure. The viscosity of the low-viscosity liquid is preferably 0.3 mPa-s or more, because the superior initial characteristics are achieved. For more detail, if the low-viscosity liquid has a viscosity less than 0.3 mPa-s, the volatility tends to be high. Thus, even if the low-viscosity liquid is impregnated into the porous structure, it evaporates, and hardly contributes to the improvement of the wettability of the electrolyte. Especially, the viscosity is preferably 0.4 mPa-s or more and 0.8 mPa-s or less, and, more preferably, 0.4 mPa-s or more and 0.7 mPa-s or less, because the higher effects are achieved. The low-viscosity liquid, for example, are acetonitrile, dimethyl carbonate, ethylmethyl carbonate, or a liquid containing electrolytic salt (electrolytic solution) which is obtained by dissolving the above-mentioned redox electrolytic salt or the like into a solvent such as acetonitrile, dimethyl carbonate, and ethylmethyl carbonate. Among them, the electrolytic solution is preferably used as the low-viscosity liquid, because the electrolytic salt infiltrates into the porous structure more easily.

Next, after removing the extra low-viscosity liquid, the high viscosity material is injected. Then, the electrolyte is optionally adjusted so as to obtain a predetermined composition, and thereby the electrolyte inclusion 30 is formed. Here, the high-viscosity material is arbitrarily selected as long as the liquid has a viscosity higher than that of the low-viscosity liquid. However, it is preferable that the high-viscosity material contains the electrolytic salt, that is, the high-viscosity material is the electrolyte having a viscosity higher than that of the low-viscosity liquid. In the case where the high-viscosity material contains the electrolytic salt, the manufacturing process is simplified in comparison with the case of the high-viscosity material containing no electrolytic salt, because the step of adding the electrolytic salt after injecting the high-viscosity material is unnecessary. As the high-viscosity material, the material having a viscosity of 1.9 mPa-s or more is preferable, because the high durability is achieved. The high-viscosity material may be a solvent containing no electrolytic salt. In that case, after injecting the high-viscosity material, the electrolytic salt is added so as to obtain a predetermined composition, and thereby the electrolyte inclusion 30 is formed.

Then, the pores for injecting the electrolytes are sealed. Thereby, the photoelectric conversion device shown in FIGS. 1 and 2 is completed.

In a second manufacturing method, the working electrode 10 and the facing electrode 20 are manufactured by using the same process as in the first manufacturing method. At this time, the pores for injecting the electrolytes are not made on the facing substrate 20.

Next, the low-viscosity liquid is dropped or applied to the metal oxide semiconductor layer 12 of the working electrode 10 under vacuum atmosphere, and thus the low-viscosity liquid infiltrates into the porous structure of the metal oxide semiconductor layer 12. Thereby, the low-viscosity liquid works in the same way as in the first manufacturing method. As the low-viscosity liquid, the same low-viscosity liquid as in the first manufacturing method may be used. Next, after removing the extra low-viscosity liquid, the high-viscosity material is dropped or applied to the metal oxide semiconductor layer 12. The electrolyte is optionally adjusted so as to obtain a predetermined composition. As the high-viscosity material, the same high-viscosity material as in the first manufacturing method may be used, and it works in the same way.

Next, the face of the working electrode 10, which carries the dye 14, and the face of the facing electrode 20, where the conductive layer 22 is formed, are stuck together under vacuum atmosphere with a spacer in between so as to maintain a predetermined space and face these faces. Finally, the whole is sealed, and thereby the photoelectric conversion device shown in FIGS. 1 and 2 is completed.

In this photoelectric conversion device, when the dye 14 carried by the working electrode 10 is subjected to light (sunlight or visible light at the same level as the sunlight), the dye 14 is erected by absorbing the light and injects the electrons into the metal oxide semiconductor layer 12. Thus, the electron travels to the facing electrode. On the other hand, in the electrolyte inclusion 30, a redox reaction is repeated in accordance with the travel of the electron between the working electrode 10 and the facing electrode 20. Thus, the electron continuously travels between the working electrode 10, the facing electrode 20, and the electrolyte inclusion 30 so that the photoelectric conversion is constantly performed.

In the method of manufacturing the photoelectric conversion device, in the step of forming the electrolyte inclusion 30, the low-viscosity liquid is impregnated into the porous structure of the metal oxide semiconductor material 12, and then the high-viscosity material having a viscosity higher than that of the low-viscosity liquid is filled between the working electrode 10 and the facing electrode 20. Thereby, the low-viscosity material functions so as to improve the wettability of the porous structure, and at least a part of compositions of the high-viscosity material easily infiltrate into the porous structure. Several methods are available for impregnating the electrolytes in the step of forming the electrolyte inclusion 30. For example, the high-viscosity material may contain the electrolytic salt. In this case, the electrolytic salt is quickly diffused in the porous structure. Alternatively, the low-viscosity liquid may contain the electrolytic salt. In this case, the electrolytic salt in the porous structure is diffused in the high-viscosity material. Obviously, both of the high-viscosity material and the low-viscosity liquid may contain the electrolytic salt. Moreover, the step of impregnating the electrolytic salt between the working electrode 10 and the facing electrode 20 may be included, separately from the step of impregnating the low-viscosity liquid and the step of filling the high-viscosity material. In this case, the electrolytic salt is also quickly diffused in the porous structure. In any of these cases, in the electrolyte inclusion 30 at least at an initial stage, the electrolyte having a low viscosity is distributed so as to be enclosed in the porous structure. Thus, the electron quickly travels between the working electrode 10 and the electrolyte inclusion 30 at the initial stage. Moreover, a large part of the electrolyte inclusion 30 is composed of the electrolyte having a high viscosity. Therefore, the leakage of the electrolyte is suppressed even under the high-temperature environment.

According to this photoelectric conversion device, in the case where the photoelectric conversion device is manufactured by the manufacturing method described above, at least at the initial stage, the electrolyte inclusion 30 has a configuration as described in the following. The electrolyte inclusion 30 contains the first electrolyte and the second electrolyte, the first electrolyte has a viscosity lower than that of the second electrolyte, and the concentration ratio of the first electrolyte to the second electrolyte is higher in the porous structure of the metal oxide semiconductor layer 12 in the working electrode 10 in comparison with the region except in the porous structure. Thus, the electron quickly travels between the working electrode 10 and the electrolyte inclusion 30 in the initial state of the photoelectric conversion device. Moreover, a large part between the working electrode 10 and the facing electrode 20 contains the electrolyte having the high viscosity so that the leakage of the electrolyte is suppressed even under the high-temperature environment. Therefore, the durability is maintained and the initial characteristics are improved. Also, if the viscosity of the second electrolyte is 1.9 mPa-s or more, the initial characteristics are improved and the high durability is achieved.

According to the method of manufacturing the photoelectric conversion device, the low-viscosity liquid is impregnated into the porous structure of the metal oxide semiconductor layer 12. After that, there is the step of filling, between the working electrode 10 and the facing electrode 20, the high-viscosity material having a viscosity higher than that of the low-viscosity liquid. Thereby the leakage of the electrolytes is suppressed and the durability is maintained. Because the electron quickly travels between the working electrode 10 and the electrolyte inclusion 30 at the initial stage, the initial characteristics are improved. Moreover, when the liquid having a viscosity of 0.3 mPa-s or more is used as the low-viscosity material, or the material having a viscosity of 1.9 mPa-s or more is used as the high-viscosity material, the initial characteristics are improved and the high durability is achieved. Further, when the material containing the electrolytic salt (electrolyte) is used as at least one of the low-viscosity liquid and the high-viscosity material, the manufacturing process is simplified. Especially, when the electrolyte containing the electrolytic salt is used as both of the low-viscosity liquid and the high-viscosity material, the initial characteristics are further improved.

### Second Embodiment

In a second embodiment, the configuration is the same as in the first embodiment except that an electrolyte inclusion 30 has an electrolyte including a support material, and that at least a part of the electrolytes are in a semisolid state.

Similarly to the first embodiment, the electrolyte inclusion 30 contains at least two or more electrolytes, and, in these electrolytes, there are a first electrolyte and a second electrolyte having a viscosity higher than that of the first electrolyte. Moreover, at least one of these electrolytes includes the above-mentioned liquid electrolyte (electrolytic solution) as well as the support material supporting the electrolytic solution, and is in the semisolid state. The term “semisolid state” means the state having a high fluidity like liquid, or the state different from the state having no fluidity like solid. For example, the semisolid state indicates a large concept including a paste state, a gel state, and the like.

The concentration ratio of the first electrolyte to the second electrolyte in the electrolyte inclusion 30 is higher in the porous structure of a metal oxide semiconductor layer 12 in comparison with the region except in the porous structure. That is, the electrolyte present in the porous structure of the metal oxide semiconductor layer 12 has a composition different from that of the region except in the porous structure, for example, that of the electrolyte present on a facing electrode 20 side. Specifically, the viscosity of the electrolyte present in the porous structure of the metal oxide semiconductor layer 12 is lower than that of the electrolyte present in any of the regions except in the porous structure. The viscosity of the second electrolyte is preferably 1.9 mPa-s or more, because the durability is improved.

These electrolytes contain an electrolytic salt, and optionally may contain a solvent such as an organic solvent. The electrolytic salt and the solvent may include the same materials as in the first embodiment.

As the support material included in the semisolid electrolytes, for example, there are a particle and a high polymer compound. These may be singly used, or plurally used by mixing them. As the particle, for example, there are the particle having a conductivity, a semi-conductivity or insulation properties and the particle catalyzing a redox reaction. These may be singly used, or plurally used by mixing them. Among them, the particle having a conductivity (conductive particle) is preferable, the particle catalyzing the redox reaction is more preferable, and the particle having the conductivity and catalyzing the redox reaction is further preferable. When the particle has the conductivity, the electric resistance of the electrolyte inclusion 30 is lowered. When the particle catalyzes the redox reaction, the redox reaction is improved. In each of the cases, the conversion efficiency is improved. When the particle has the conductivity and catalyzes the redox reaction, the especially-high efficiency is achieved.

As such particles, for example, there are a metal oxide particle containing a metal oxide, and a carbon particle containing a carbon material. These may be singly used, or plurally used by mixing them. As the metal oxide particles, for example, there are a titanium oxide particle, a silica gel (silicon oxide; SiO₂) particle, a zinc oxide (ZnO) particle, a tin oxide (SnO₂) particle, a titanium acid cobalt (CoTiO₃) particle, and a titanium acid barium (BaTiO₂) particle. As the carbon particle, there are a crystalline particle such as graphite, and an amorphous particle such as activated carbon and carbon black. In addition to these, there are graphene, carbon nanotube, fullerene, and the like. As the graphite, there are artificial graphite, natural graphite, and the like. As the carbon black, there are furnace black, oil furnace, channel black, acethylene black, thermal black, ketjen black, and the like. As the carbon particle, the carbon black or the carbon nanotube is especially preferable, because the high efficiency is achieved. Also, as the carbon particle, a particle having a high DBP-absorption (JIS K6217-4) is preferable, because it is thought that the absorption of electrolytic salt per particle increases, and this contributes to the improvement of the conversion efficiency.

Among them, the carbon particle is preferable as the particle. This is because the carbon particle has the conductivity and catalyzes the redox reaction as well so that the high efficiency is achieved. As the carbon particle, the particle having the high conductivity is preferable, and, moreover, the particle having a large specific surface area is preferable. This is because the conductivity of the electrolyte inclusion 30 becomes high and, moreover, the contact area with the electrolytic solution becomes large so that the redox reaction is favorably catalyzed. For the conductivity of the carbon particle, the bulk resistance of the carbon particle is preferably 10 Ωcm or less (0.1 Ωm or less). Thereby, the electric resistance of the electrolyte inclusion 30 is sufficiently suppressed so that the internal resistance of the device is also sufficiently suppressed. For more detail, in the dye-sensitized photoelectric conversion device, the resistance of the component material is generally one of the major factors for the loss of the conversion efficiency. Among them, the conductive material having light transmissivity, which is used for the conductive substrate has a relatively-high electric resistance. For example, FTO (F—SnO₂) has a resistance of approximately 10 Ωcm. For this reason, when the carbon particle having a resistance lower than that of the conductive material which has light transmissivity and is used as the component material of the conductive layer 11B is used, that is, when the carbon particle having a bulk resistance of 10 Ωcm or less is used, the internal resistance of the device is suppressed low, and the sufficient conversion efficiency is achieved.

As the high polymer compound, for example, there are polyvinylidene fluoride, copolymer of vinylidene fluoride and propylene hexafluoride, polyacrylonitrile, and polyaniline.

The photoelectric conversion device including such an electrolyte inclusion 30 may be manufactured by, for example, the above-mentioned second manufacturing method.

First, by the same process as in the second manufacturing method, the working electrode 10 and the facing electrode 20 are manufactured. Next, the low-viscosity liquid is dropped or applied to the metal oxide semiconductor layer 12 of the working electrode 10 under vacuum atmosphere, and thereby the low-viscosity liquid infiltrates into the porous structure of the metal oxide semiconductor layer 12.

Next, after removing the extra low-viscosity liquid, the high-viscosity material is dropped or applied to the metal oxide semiconductor layer 12. Then, the electrolyte is optionally adjusted so as to obtain a predetermined composition. Here, the high-viscosity material is arbitrarily selected as long as the material has a viscosity higher than that of the low-viscosity liquid. However, the material preferably includes the above-mentioned support material. This is because the support material is easily included in the electrolyte inclusion 30 by being dispersed or diffused with a high uniformity so that the higher durability is achieved. The high-viscosity material preferably contains the electrolytic salt, because of the same reason as described above.

In the case where the high-viscosity material including the support material is prepared, for example, the particle is dispersed in the liquid such as the electric solution so as to obtain a paste state or a slurry state. Alternatively, for example, the liquid such as the electric solution is mixed with the high polymer compound and heated so as to obtain a sol state or a gel state.

Finally, similarly to the second manufacturing method described above, the working electrode 10 and the facing electrode 20 are stuck together with a spacer in between. The whole is sealed, and thereby the photoelectric conversion device shown in FIGS. 1 and 2 is completed.

According to the photoelectric conversion device in the present embodiment, in the case where the photoelectric conversion device is manufactured by the manufacturing method described above, at least at the initial stage, the electrolyte inclusion 30 has a configuration as described in the following. The electrolyte inclusion 30 contains the first electrolyte and the second electrolyte, the first electrolyte has a viscosity lower than that of the second electrolyte, and the concentration ratio of the first electrolyte to the second electrolyte is higher in the porous structure of the metal oxide semiconductor layer 12 in the working electrode 10 in comparison with the region except in the porous structure. In this case, the support material is included in the electrolyte inclusion 30. Therefore, the higher durability is maintained and the initial characteristics are improved. Other operational effects in the photoelectric conversion device are the same as in the photoelectric conversion device of the first embodiment.

According to the method of manufacturing the photoelectric conversion device in the present embodiment, the low-viscosity liquid is impregnated into the porous structure of the metal oxide semiconductor layer 12. After that, there is the step of filling, between the working electrode 10 and the facing electrode 20, the high-viscosity material having a viscosity higher than that of the low-viscosity liquid and including the support material such as particles. Thereby, the electrolyte inclusion 30 is formed. Therefore, the low-viscosity liquid functions so as to improve the wettability of the porous structure, and at least a part of compositions in the high-viscosity material easily infiltrates into the porous structure. In the formed electrolyte inclusion 30, at least at the initial stage, the electrolyte having the low viscosity is distributed so as to be enclosed in the porous structure, and, meanwhile, a large part is composed of the electrolytes having the high viscosity. Therefore, the higher durability is maintained, and the initial characteristics are improved.

In this case, as the high-viscosity material, a material containing at least one of the metal oxide particle and the carbon particle may be used. As the metal oxide particle, at least one of the zinc oxide particle and the titanium oxide may be used. As the carbon particle, at least one of carbon black and carbon nanotube may be used.

In the present embodiment, as an example, it is explained that the electrolyte inclusion 30 is formed by using the high-viscosity material containing the high polymer compound. However, the electrolyte inclusion 30 containing the high polymer compound as the support material may be formed by other methods. In the case where the electrolyte inclusion 30 is formed by other methods, for example, a polymerizable compound such as a monomer of the high polymer compound is used as the high-viscosity material. Specifically, after the low-viscosity liquid is impregnated into the porous structure of the working electrode 10, the extra low-viscosity liquid is removed. Next, the high-viscosity material such as the monomer of the high polymer compound is injected, or dropped or applied to the metal oxide semiconductor layer 12. Then, the electrolytic salt is optionally added and the electrolyte is adjusted so as to obtain a desired composition. Finally, the monomer and the like are polymerized. Thus, the electrolyte inclusion 30 containing the gel-state electrolyte is formed. In this case, the operational effects similar to the first embodiment and the second embodiment are also obtained.

### EXAMPLES

Specific examples of the present invention will be described in detail.

### Example 1-1

As a specific example of the photoelectric conversion device described in the above embodiment, a dye-sensitized solar cell was manufactured with following procedures.

First, a working electrode 10 was manufactured. A metal oxide semiconductor layer 12 of zinc oxide with an area of 1 cm² was formed by electrolytic deposition on one surface of a conductive substrate 11 made of a conductive glass substrate (F—SnO₂) with a size of 2.0 cm in length, 1.5 cm in width, and 1.1 mm in thickness. For the electrolytic deposition, an electrolytic bath liquid of 40 cm³, a counter electrode of zinc plate, and a reference electrode of silver/silver chloride electrode were used, where the electrolytic bath was adjusted so as to have a concentration of eosin Y (30 μmol/dm³), zinc chloride (5 mmol/dm³), and potassium chloride (0.09 mol/dm³) with respect to water. The electrolytic bath was bubbled with oxygen for 15 minutes. Then, with constant-potential electrolysis of an electric potential of 1.0 V, the electrolytic bath was bubbled for 60 minutes at a temperature of 70° C. and deposited on a surface of the conductive substrate 11. This substrate was dipped into potassium hydroxide aqueous solution (pH11) without being dried, and then eosin Y was washed away. Next, the substrate was dried for 30 minutes at 150° C., and thereby the metal oxide semiconductor layer 12 was formed. Next, the metal oxide semiconductor layer 12 was dipped into ethanol solution (5 mmol/dm³) of D102 dye (manufactured by Mitsubishi Paper Mills Ltd.) as an organic dye and a dye 14 was carried. Thereby, the working electrode 10 was manufactured.

Next, a facing electrode 20 was manufactured. A conductive layer 22 (100 nm) of platinum was formed by sputtering on one surface of a conductive substrate 21 made of a conductive glass substrate (F—SnO₂) with a size of 2.0 cm in length, 1.5 cm in width, and 1.1 mm in thickness. There were two pores (φ 1 mm) opened for injecting an electrolytic inclusion 30 on the facing substrate 20.

Next, the face of the working electrode 10, which carried the dye 14, and the face of the facing electrode 20 on the conductive layer 22 side were faced each other and stuck together with a spacer having a thickness of 50 μm in between so that a predetermined space was maintained between the working electrode 10 and the facing electrode 20.

Next, a low-viscosity liquid, which is an electrolyte containing a solvent and an electrolytic salt, was prepared. Also, a high-viscosity material, which is an electrolyte having a viscosity higher than that of the low-viscosity liquid was prepared. The low-viscosity liquid was adjusted so as to obtain a concentration of the electrolytic salt in the low-viscosity liquid as 0.6 mol/dm³ (DMHImI) and 0.05 mol/dm³ (I₂), by using acetonitrile (AN) as the solvent and dimethylhexyl imidazolium iodide (DMHImI) and iodine (I₂) as a redox electrolytic salt which was an electrolytic salt. The high-viscosity material was adjusted in the same way as the low-viscosity liquid, except that, instead of AN, sulfolane was used as the solvent. In this case, the viscosity of the low-viscosity liquid and the viscosity of the high-viscosity material (electrolyte) were measured under a room-temperature atmosphere (23° C.), and the results were obtained as shown in table 1. For the measurement of the viscosity, visco mate VM-100 (manufactured by Yamaichi Electronics Co., Ltd.) was used as a viscometer. In subsequent examples and comparative examples, the viscosity measurement of the low-viscosity liquid and the high-viscosity material was, conducted in the same way as described above.

Next, the adjusted low-viscosity liquid was injected between the working electrode 10 and the facing electrode 20 from the pores opened on the facing electrode 20. Then, the extra low-viscosity liquid was removed so that a small amount of the low-viscosity liquid impregnated into the metal oxide semiconductor layer 12 remained. At this time, the weight of the remaining low-viscosity liquid impregnated into the metal oxide semiconductor layer 12 was 0.3 mg. Next, the electrolyte as the high-viscosity material was injected, and thereby the electrolyte inclusion 30 was formed. Finally, the whole was sealed and a dye-sensitized solar cell was obtained.

### Examples 1-2 to 1-7

The same process as in example 1-1 was performed except that, instead of sulfolane, propylene carbonate (PC; example 1-2), a solvent by mixing PC and ethylene carbonate with a weight ratio of 1:1 (PC:EC=1:1; example 1-3), dimethylsulfoxide (DMSO; example 1-4), a solvent by mixing PC and EC with a weight ratio of 1:2 (example 1-5), γ butyrolactone (GBL; example 1-6), and ethyl methyl carbonate (EMC; example 1-7) were used as the solvent of the high-viscosity material.

### Example 1-8

The same process as in example 1-1 was performed except that 1-methyl-3-propyl imidazolium iodide (MPImI) as an ionic liquid and I₂ were used as the high-viscosity material. At this time, an electrolyte was adjusted by mixing MPImI and I₂ so that a concentration of I₂ in a high-viscosity material was set as 0.35 mol/dm³.

### Examples 1-9 to 1-14

The same process as in examples 1-1 to 1-4, 1-6, and 1-7 was performed except that, instead of AN, dimethyl carbonate (DMC) was used as a solvent of a low-viscosity liquid. At this time, the weight of the low-viscosity liquid impregnated into the metal oxide semiconductor layer 12 was 0.3 mg.

### Example 1-15

The same process as in example 1-8 was performed except that, instead of DMHImI, tetrapropyl ammonium iodide (TPAI) was used as an electrolytic salt of a low-viscosity liquid. At this time, the electrolytic salt was adjusted so that a concentration of TPAI in the low-viscosity liquid was 0.5 mol/dm³.

### Comparative Examples 1-1 to 1-8

The same process as in examples 1-1 to 1-8 was performed except that an electrolyte inclusion 30 was formed without using a low-viscosity liquid. That is, a high-viscosity material as in examples 1-1 to 1-8 was used as an electrolyte.

### Comparative Example 1-9

The same process as in comparative example 1-1 was performed except that an electrolyte was adjusted so as to have the same composition as the electrolyte inclusion 30 in example 1-15, and used. At this time, the electrolyte was adjusted in the following way. A mixed liquid (A-liquid) by mixing MPImI and 12 with a concentration of 12 as 0.35 mol/dm³, and a mixed liquid (B-liquid) by mixing AN and TPAI with a concentration of TPAI as 0.5 mol/dm³ were used so that the electrolyte inclusion 30 contains B-liquid of 0.3 mg.

### Comparative Examples 1-10 and 1-11

The same process as in comparative example 1-1 was performed except that DMC (comparative example 1-10) and AN (comparative example 1-11) were used as a solvent of an electrolyte.

Initial characteristics and a durability of a dye-sensitized solar cell in examples 1-1 to 1-15 and comparative examples 1-1 to 1-11 were investigated. Results shown in tables 1 and 2 were obtained.

For investigating the initial characteristics, a short circuit current density (Jsc) and a conversion efficiency were measured when 5 minutes passed and 3 hours passed after manufacturing the dye-sensitized solar cell. Thereby, the initial efficiency ratio was obtained. The initial efficiency ratio (%) was calculated as: (Jsc or conversion efficiency when 5 minutes passed after manufacture/Jsc or conversion efficiency when 3 hours passed)×100. In this case, the short circuit current density and the conversion efficiency were obtained in the following way by using a solar simulator with a light source of AM 1.5 (1000 W/m²). First, an open voltage of the dye-sensitized solar cell was swept by a source meter, and the short circuit current density (Jsc: mA/cm²) was measured. The conversion efficiency (η:%) was obtained in the following way. A maximum output as a product of the open voltage and the short circuit current density was divided by the light intensity per 1 cm² and then the obtained value was multiplied by 100 for percent figures. That is, the conversion efficiency was expressed as: (maximum output/light intensity per 1 cm²)×100.

For investigating the durability, the dye-sensitized solar cell was subjected to a high-temperature atmosphere, and the presence or absence of generation of bubbles in an electrolyte inclusion 30 and leakage of the electrolyte were confirmed by visual observation. For more detail, the temperature of the dye-sensitized solar cell in a constant temperature bath was risen by 10° C. up to 190° C., and the temperature when generation of the bubbles or the leakage of the electrolyte was observed was regarded as an upper-limit temperature.

TABLE 1

| | | | | HIGH-VISCOSITY MATERIAL | | | INITIAL | | |
|---|---|---|---|---|---|---|---|---|---|
| | LOW-VISCOSITY LIQUID | | | (ELECTROLYTE) | | | EFFICIENCY | | UPPER- |
| | TYPE | | | TYPE | | | RATIO (%) | | LIMIT |
| | ELECTROLYTE | | VISCOSITY | ELECTROLYTE | | VISCOSITY | | CONVERSION | TEMP. |
| | SALT | SOLVENT | (mPa · s) | SALT | SOLVENT | (mPa · s) | Jsc | EFFICIENCY | (° C.) |
| EXAMPLE | DMHImI + I2 | AN | 0.4 | DMHImI + I2 | SULFOLANE | 11 | 79 | 80 | 190< |
| 1-1 | | | | | | | | | |
| EXAMPLE | | | | | PC | 2.9 | 92 | 94 | 190< |
| 1-2 | | | | | | | | | |
| EXAMPLE | | | | | PC:EC = 1:1 | 2.7 | 95 | 98 | 190< |
| 1-3 | | | | | | | | | |
| EXAMPLE | | | | | DMSO | 2.5 | 80 | 81 | 190< |
| 1-4 | | | | | | | | | |
| EXAMPLE | | | | | PC:EC = 1:2 | 2.4 | 95 | 98 | 190< |
| 1-5 | | | | | | | | | |
| EXAMPLE | | | | | GBL | 1.9 | 83 | 82 | 190< |
| 1-6 | | | | | | | | | |
| EXAMPLE | | | | | EMC | 0.8 | 98 | 98 | 130 |
| 1-7 | | | | | | | | | |
| EXAMPLE | | | | MPImI + I2 | — | 1000-2000 | 93 | 98 | 190< |
| 1-8 | | | | | | | | | |
| EXAMPLE | DMHImI + I2 | DMC | 0.7 | DMHImI + I2 | SULFOLANE | 11 | 70 | 76 | 190< |
| 1-9 | | | | | | | | | |
| EXAMPLE1- | | | | | PC | 2.9 | 90 | 90 | 190< |
| 10 | | | | | | | | | |
| EXAMPLE1- | | | | | PC:EC = 1:1 | 2.7 | 94 | 93 | 190< |
| 11 | | | | | | | | | |
| EXAMPLE1- | | | | | DMSO | 2.5 | 77 | 79 | 190< |
| 12 | | | | | | | | | |
| EXAMPLE1- | | | | | GBL | 1.9 | 80 | 80 | 190< |
| 13 | | | | | | | | | |
| EXAMPLE1- | | | | | EMC | 0.8 | 96 | 94 | 130 |
| 14 | | | | | | | | | |
| EXAMPLE1- | TPAI + I2 | AN | 0.4 | MPImI + 12 | — | 1000-2000 | 96 | 100 | 190< |
| 15 | | | | | | | | | |

TABLE 2

| | | | | HIGH-VISCOSITY MATERIAL | | | INITIAL | | |
|---|---|---|---|---|---|---|---|---|---|
| | LOW-VISCOSITY LIQUID | | | (ELECTROLYTE) | | | EFFICIENCY | | UPPER- |
| | TYPE | | | TYPE | | | RATIO (%) | | LIMIT |
| | ELECTROLYTE | SOL- | VISCOSITY | ELECTROLYTE | | VISCOSITY | | CONVERSION | TEMP. |
| | SALT | VENT | (mPa · s) | SALT | SOLVENT | (mPa · s) | JSC | EFFICIENCY | (° C.) |
| COMPARATIVE | — | — | — | DMHImI + I₂ | SULFOLANE | 11 | 42 | 44 | 190< |
| EXAMPLE | | | | | | | | | |
| 1-1 | | | | | | | | | |
| COMPAPATIVE | | | | | PC | 2.9 | 49 | 62 | 190< |
| EXAMPLE | | | | | | | | | |
| 1-2 | | | | | | | | | |
| COMPARATIVE | | | | | PC:EC = 1:1 | 2.7 | 44 | 74 | 190< |
| EXAMPLE | | | | | | | | | |
| 1-3 | | | | | | | | | |
| COMPARATIVE | | | | | DMSO | 2.5 | 52 | 52 | 190< |
| EXAMPLE | | | | | | | | | |
| 1-4 | | | | | | | | | |
| COMPARATIVE | | | | | PC:EC = 1:2 | 2.4 | 44 | 68 | 190< |
| EXAMPLE | | | | | | | | | |
| 1-5 | | | | | | | | | |
| COMPARATIVE | | | | | GBL | 1.9 | 41 | 69 | 190< |
| EXAMPLE | | | | | | | | | |
| 1-6 | | | | | | | | | |
| COMPARATIVE | | | | | EMC | 0.8 | 92 | 92 | 130 |
| EXAMPLE | | | | | | | | | |
| 1-7 | | | | | | | | | |
| COMPARATIVE | | | | MPImI + I₂ | — | 1000-2000 | 41 | 33 | 190< |
| EXAMPLE | | | | | | | | | |
| 1-8 | | | | | | | | | |
| COMPARATIVE | | | | MPImI + I₂ + | AN | 1000-2000 | 30 | 36 | 190< |
| EXAMPLE | | | | TPAI | | | | | |
| 1-9 | | | | | | | | | |
| COMPARATIVE | | | | DMHImI + I₂ | DMC | 0.7 | 94 | 94 | 110 |
| EXAMPLE | | | | | | | | | |
| 1-10 | | | | | | | | | |
| COMPARATIVE | | | | | AN | 0.4 | 100 | 100 | 110 |
| EXAMPLE | | | | | | | | | |
| 1-11 | | | | | | | | | |

As shown in table 1, in examples 1-1 to 1-15 where a low-viscosity liquid was impregnated into a metal oxide semiconductor layer 12, and then a high-viscosity material (electrolyte) was injected so as to form the electrolyte inclusion 30, the initial efficiency ratio of Jsc and the conversion efficiency was higher in comparison with comparative examples 1-1 to 1-9 where the electrolyte having the same composition as in corresponding examples was injected without using the low-viscosity liquid, respectively. In examples 1-1 to 1-15, the upper-limit temperature was 130° C. or over 190° C. In comparative examples 1-10 and 1-11 where acetonitrile or dimethyl carbonate was used as a solvent of the electrolyte, the initial efficiency ratio of Jsc and the conversion efficiency was 90% or more, but the upper-limit temperature was remarkably low as 110° C. That is, in comparative examples 1-10 and 1-11 where the upper-limit temperature was 110° C., the durability was not maintained. Especially, when comparing between example 1-15 and comparative example 1-9 where the composition of the electrolyte in the electrolyte inclusion 30 was the same as a whole, the upper-limit temperature was 190° C. or more in both of the cases, but the initial efficiency ratio of Jsc and the conversion efficiency was remarkably higher in example 1-9. These results indicated that, regardless of the types of electrolytic salts and the like, the low-viscosity liquid improved wettability of the electrolyte as the high-viscosity material with respect to a porous structure of the metal oxide semiconductor layer 12, and thus the electrolytic salt quickly infiltrated into the porous structure.

When comparing between examples 1-1 to 1-4, and 1-6 to 1-8 where the viscosity of the low-viscosity liquid was 0.4 mPa-s, and examples 1-9 to 1-14 where the viscosity was 0.7 mPa-s, the upper-limit temperature was the same in all of the cases, but the initial efficiency ratio of Jsc and the conversion efficiency was higher in examples 1-1 to 1-4, and 1-6 to 1-8. Moreover, in examples 1-1 to 1-6, 1-8 to 1-13, and 1-15 where the viscosity of the high-viscosity material was 1.9 mPa-s or more, the upper-limit temperature was higher in comparison with examples 1-7 and 1-14 where the viscosity was 0.8 mPa-s.

In the present example, the case where the liquid containing no electrolytic salt was used as the low-viscosity liquid was not shown. However, even in the case where acetonitrile with a viscosity of 0.3 mPa-s was used as the low-viscosity liquid, the same results as in examples 1-1 to 1-8 were obtained.

From this, it was confirmed that the durability was maintained and the initial characteristics were improved in the photoelectric conversion device which was manufactured through the step of filling, between the working electrode 10 and the facing electrode 20, the high-viscosity material having a viscosity higher than that of the low-viscosity liquid, after the low-viscosity liquid was impregnated into the porous structure of the metal oxide semiconductor layer 12. In this case, the liquid containing the electrolytic salt with a viscosity of 0.3 mPa-s or more was used as the low-viscosity liquid, and the liquid containing the electrolytic salt with a viscosity of 1.7 mPa-s or more was used as the high-viscosity material. Thereby, it was confirmed that the initial characteristics were improved, and the high durability was achieved.

### Examples 2-1 to 2-5

The same process as in example 1-8 was performed except that particles were added as a high-viscosity material. In the case where a electrolyte inclusion 30 was formed by using this high-viscosity material, the high-viscosity material was adjusted in the following way. The particles were added to a mixture of MPImI and I₂ having a concentration of I₂ as 0.35 mol/dm³, and kneaded so as to obtain the particles of 20 weight %. At this time, as shown in table 2, carbon black (CB; SUNBLACK 935 manufactured by Asahi Carbon Co., Ltd.) (example 2-1), carbon nanotube (CN; 90% SWCNT manufactured by Sigma-Aldrich Co., Ltd.) (example 2-2), a mixture of CB and CN with a weight ratio of 1:1, zinc oxide particles (ZnO; Zincox Super F3 manufactured by Hakusui Tech Co., Ltd.), and titanium oxide particles (TiO₂; P-25 manufactured by Nippon Aerosil Co., Ltd.) were used as the particles.

Next, a low-viscosity liquid was dropped on a metal oxide semiconductor layer 12 of a working electrode 10 under vacuum atmosphere, and then the extra low-viscosity liquid was removed. The high-viscosity material containing the particles was applied to the metal oxide semiconductor layer 12. The face of the working electrode 10, which carried the dye 14, and the face of the facing electrode 20, where the conductive layer 22 was formed, were stuck together with a spacer in between so as to maintain a predetermined space and face these faces. In addition, no pores for injecting the electrolytes were opened on the facing substrate 20 used at this time.

### Examples 2-6 to 2-10

The same process as in examples 2-1 to 2-5 was performed except that, instead of AN, DMC was used as a solvent of a low-viscosity liquid.

### Comparative Examples 2-1 to 2-5

The same process as in examples 2-1 to 2-5 was performed except that an electrolyte inclusion 30 was formed without using a low-viscosity liquid.

Initial characteristics and a durability of dye-sensitized solar cells in examples 2-1 to 2-10 and comparative examples 2-1 to 2-5 were investigated. The results shown in table 3 were obtained.

TABLE 3

| | | | | HIGH-VISCOSITY MATERIAL | | | INITIAL | | |
|---|---|---|---|---|---|---|---|---|---|
| | LOW-VISCOSITY LIQUID | | | (ELECTROLYTE) | | | EFFICIENCY | | UPPER- |
| | TYPE | | | TYPE | | | RATIO (%) | | LIMIT |
| | ELECTROLYTE | SOL- | VISCOSITY | ELECTROLYTE | | VISCOSITY | | CONVERSION | TEMP. |
| | SALT | VENT | (mPa · s) | SALT | SOLVENT | (mPa · s) | JSC | EFFICIENCY | (° C.) |
| EXAMPLE 2-1 | DMHImI + I₂ | AN | 0.4 | MPImI + I₂ | CB | 10000< | 71 | 60 | 190< |
| EXAMPLE 2-2 | | | | | CN | 10000< | 74 | 60 | 190< |
| EXAMPLE 2-3 | | | | | CB:CN = 1:1 | 10000< | 74 | 61 | 190< |
| EXAMPLE 2-4 | | | | | ZnO | 10000< | 72 | 60 | 190< |
| EXAMPLE 2-5 | | | | | TiO₂ | 10000< | 70 | 58 | 190< |
| EXAMPLE 2-6 | DMHImI + I₂ | DMC | 0.7 | MPImI + I₂ | CB | 10000< | 70 | 56 | 190< |
| EXAMPLE 2-7 | | | | | CN | 10000< | 70 | 55 | 190< |
| EXAMPLE 2-8 | | | | | CB:CN = 1:1 | 10000< | 71 | 58 | 190< |
| EXAMPLE 2-9 | | | | | ZnO | 10000< | 66 | 55 | 190< |
| EXAMPLE 2- | | | | | TiO₂ | 10000< | 68 | 54 | 190< |
| 10 | | | | | | | | | |
| COMPARATIVE | — | — | — | MPImI + I₂ | CB | 10000< | 50 | 49 | 190< |
| EXAMPLE 2-1 | | | | | | | | | |
| COMPARATIVE | | | | | CN | 10000< | 52 | 49 | 190< |
| EXAMPLE 2-2 | | | | | | | | | |
| COMPARATIVE | | | | | CB:CN = 1:1 | 10000< | 51 | 51 | 190< |
| EXAMPLE 2-3 | | | | | | | | | |
| COMPARATIVE | | | | | ZnO | 10000< | 48 | 48 | 190< |
| EXAMPLE 2-4 | | | | | | | | | |
| COMPARATIVE | | | | | TiO₂ | 10000< | 44 | 47 | 190< |
| EXAMPLE 2-5 | | | | | | | | | |

As shown in table 3, in the case where a high-viscosity material containing particles and having a viscosity higher than 10,000 mP·s was used, the same results as in table 1 were obtained. That is, in examples 2-1 to 2-10 where a low-viscosity liquid was impregnated into a metal oxide semiconductor layer 12, and then the high-viscosity material containing the particles was applied so as to form an electrolyte inclusion 30, an initial efficiency ratio of Jsc and a conversion efficiency was higher in comparison with comparative examples 2-1 to 2-5 where the electrolyte (high-viscosity material) having the same composition as in the corresponding examples was used without using the low-viscosity liquid. In examples 2-1 to 2-10, the upper-limit temperature was over 190° C. The results indicated that the low-viscosity liquid improved a wettability of the high-viscosity material with respect to a porous structure of the metal oxide semiconductor layer 12, and thus an electrolytic salt quickly infiltrated into the porous structure, regardless of the composition and the viscosity of the high-viscosity material.

When comparing between examples 2-1 to 2-5 where the viscosity of the low-viscosity liquid was 0.4 mPa-s, and examples 2-6 to 2-10 where the viscosity was 0.7 mPa-s, the upper-limit temperature was the same level in all of the cases, but the initial efficiency ratio of Jsc and the conversion efficiency was higher in examples 2-1 to 2-5.

From this, even if the electrolyte inclusion 30 was formed by using the high-viscosity material containing the particles, it was confirmed that the durability was maintained and the initial characteristics were improved in the photoelectric conversion device manufactured through the step of filling, between the working electrode 10 and the facing electrode 20, the high-viscosity material having a viscosity higher than that of the low-viscosity liquid, after the low-viscosity liquid infiltrated into the porous structure of the metal oxide semiconductor layer 12.

Hereinbefore, the present invention is described with the embodiments and the examples. However, the present invention is not limited to these embodiments and examples as various modifications are available. For example, the application of the photoelectric conversion device of the present invention is not always limited as described above, and other applications may be available. As the other applications, the present invention may be applied to a light sensor and the like.

It should be understood by those skilled in the art that various modifications, combinations, sub-combinations and alterations may occur depending on design requirements and other factors insofar as they are within the scope of the appended claims or the equivalents thereof.

What is claimed is:

1. A method of manufacturing a photoelectric conversion device comprising:
forming an electrolyte inclusion between a working electrode and a facing electrode, the working electrode having a porous structure which carries a dye and the facing electrode facing the working electrode on the porous structure side,
wherein forming the electrolyte inclusion includes impregnating the porous structure with a low viscosity liquid, and then filling, between the working electrode and the facing electrode, a high-viscosity material having a viscosity higher than that of the low-viscosity liquid.

2. The method of manufacturing the photoelectric conversion device according to claim 1, wherein the low-viscosity liquid is a liquid having a viscosity of 0.3 mPa-s or more.

3. The method of manufacturing the photoelectric conversion device according to claim 1, wherein the high-viscosity material is a material having a viscosity of 1.9 mPa-s or more.

4. The method of manufacturing the photoelectric conversion device according to claim 1, wherein at least one of the low-viscosity liquid and the high-viscosity material contains an electrolytic salt.

5. The method of manufacturing the photoelectric conversion device according to claim 1, wherein the high-viscosity material contains at least one of a metal oxide particle and a carbon particle.

6. The method of manufacturing the photoelectric conversion device according to claim 5, wherein the metal oxide particle includes at least one of a zinc oxide particle and titanium oxide particle, and the carbon particle includes at least one of carbon black and carbon nanotube.

7. A photoelectric conversion device comprising:
a working electrode having a porous structure which carries a dye,
a facing electrode facing the working electrode on the porous structure side, and
an electrolyte inclusion provided between the working electrode and the facing electrode, and containing a first electrolyte and a second electrolyte,
wherein the first electrolyte has a viscosity lower than that of the second electrolyte, and a concentration ratio of the first electrolyte to the second electrolyte is higher in a region of the porous structure of the working electrode as compared with in a rest region.

8. The photoelectric conversion device according to claim 7, wherein the viscosity of the second electrolyte is 1.9 mPa-s or more.
